(19) United States
(12) Patent Application Publication
(10) Pub. No.: US 2011/0163774 A1
(43) Pub. Date: Jul. 7, 2011

(54) PROBE CARD

(75) Inventors: Toshifumi MINAMI, Yokohama-Shi (JP); Hiroki Murotani, Yokohama-Shi (JP)

(73) Assignee: KABUSHIKI KAISHA TOSHIBA, Tokyo (JP)

(21) Appl. No.: 12/819,460

(22) Filed: Jun. 21, 2010

(30) Foreign Application Priority Data
Jan. 5, 2010 (JP) 2010-000529

(51) Int. Cl. G01R 1/067; G01R 31/02

(52) U.S. Cl. 324/756.03

(57) ABSTRACT

In one embodiment, a probe card includes a substrate, a probe provided on the substrate, and a contact terminal. The contact terminal is provided at a position on the substrate where the contact terminal comes in contact with the probe when a shape anomaly is generated in the probe.

### CROSS REFERENCE TO RELATED APPLICATION

This application is based upon and claims the benefit of priority from the prior Japanese Patent Application No. 2010-529, filed on Jan. 5, 2010, the entire contents of which are incorporated herein by reference.

### FIELD

Embodiments described herein relate to a probe card, for example, to a shape of a probe needle used to bring an inspection device into physical contact with an electrode of a semiconductor device when inspecting electrical characteristics of the semiconductor device, or to a structure of a mount substrate for mounting the probe needle.

### BACKGROUND

When conducting a TEG (Test Element Group) measurement of a wafer in which semiconductor devices are fabricated, a TEG pad (TEG electrode) provided in a cutoff part (kerf) for the semiconductor devices on the wafer is brought into contact with a pad contact part (electrode contact part) provided on a tip of a probe. The TEG pad is provided on the wafer for inspecting the completion of the semiconductor devices.

To fabricate the semiconductor devices on the wafer in a high integration, it is important to make it possible to miniaturize the size of the TEG pad by reducing the height (vertical width) of the pad contact part, thereby realizing the size miniaturization of the kerf. Since it is necessary to bring the probe into physical contact with the TEG pad, the probe needs to have a structure in which the probe deviation at the time of contact can be suppressed. In recent years, therefore, a probe using a MEMS (Micro Electro Mechanical System) technique has become necessary.

The probe using the MEMS technique is greatly different in structure from a conventional probe which is formed of a metal interconnect such as W (tungsten). The probe using the MEMS technique includes a pad contact part, a beam part extending from the pad contact part, and a support part which connects the beam part to a substrate. The probe using the MEMS technique has a structure of a lever in which a joint part between the beam part and the support part serves as a fulcrum point.

In such a probe, the wafer to be measured comes extremely near the joint part between the beam part and the support part, unlike the conventional metal interconnect probe. Therefore, there is a possibility that an accident of contact between the probe and the wafer might occur, due to an influence of particles attached on the back of the wafer, a level difference on the wafer, or a reduction of a clearance between the wafer and the probe caused by a degradation of the probe, and thus the probe might sustain physical damage. In the metal interconnect probe, there is a distance of approximately 5 mm between the probe and the wafer. On the other hand, in the MEMS structure, there is a distance in the range of only approximately 100 to 300 μm. The contact between the probe and the wafer poses a problem that there is a risk of occurrence of a delay in measurement time due to a slight increase of a contact resistance or due to a re-measurement, and that it becomes impossible to quantitatively control the exchange time of the probe.

According to a conventional method for detecting mechanical damage to the probe, whether there is damage or not is optically managed by monitoring a focus difference between a dummy pin and a tip of the probe, by using a CCD camera which functions as an alignment tool of a prober apparatus. In this case, however, it is necessary to conduct an inspection at the time of an alignment adjustment before measurement, and it poses a problem that whether there is damage or not cannot be determined during the measurement.

A known technique can provide a probe card which can detect whether a probe needle is in contact with an inspection object, based on a displacement of a leaf spring (see JP-A 2006-98299 (KOKAI)).

### BRIEF DESCRIPTION OF THE DRAWINGS

FIG. 1 is a cross-sectional view showing a configuration of a probe card according to a first embodiment;

FIGS. 2A to 2C illustrate cross-sectional views showing a TEG measurement of a wafer;

FIG. 3 is a top view for explaining a probe slip;

FIG. 4 is a cross-sectional view for explaining the probe slip;

FIG. 5 is a cross-sectional view showing a damage detection by using a CCD camera;

FIGS. 6A to 6C illustrate cross-sectional views showing an example of a generation process of a shape anomaly in a probe;

FIG. 7 is a cross-sectional view showing a configuration of a probe card according to a second embodiment;

FIG. 8 is a cross-sectional view showing a configuration of a probe card according to a modification of the second embodiment;

FIG. 9 is a cross-sectional view showing a configuration of a probe card according to a third embodiment; and

FIGS. 10A and 10B show cross-sectional views for comparing advantages of probe structures between the second and third embodiments.

### DETAILED DESCRIPTION

Embodiments will now be explained with reference to the accompanying drawings.

An embodiment described herein is, for example, a probe card including a substrate, a probe provided on the substrate, and a contact terminal. The contact terminal is provided at a position on the substrate where the contact terminal comes in contact with the probe when a shape anomaly is generated in the probe.

Another embodiment described herein is, for example, a probe card including a substrate, a probe provided on the substrate, and a contact terminal. The contact terminal is provided at a position on the probe where the contact terminal comes in contact with the substrate when a shape anomaly is generated in the probe.

### First Embodiment

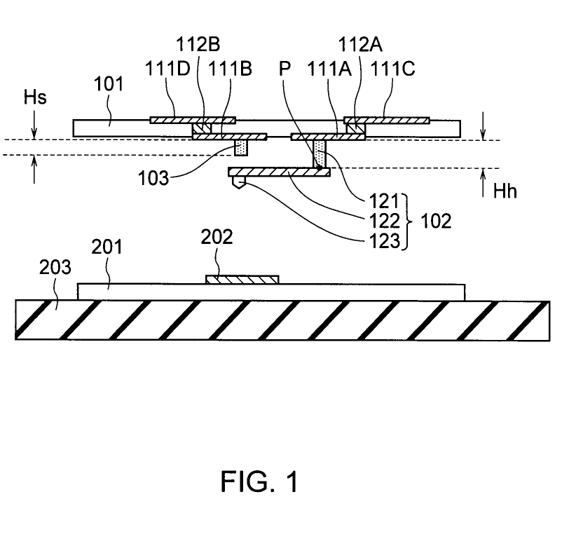

FIG. 1 is a cross-sectional view showing a configuration of a probe card according to a first embodiment.

As shown in FIG. 1, the probe card according to the present embodiment includes a substrate 101, a probe 102 provided on the substrate 101, and a contact terminal 103 provided on the substrate 101. The contact terminal 103 is provided at a position on the substrate 101 where the contact terminal 103 comes in contact with the probe 102 when a shape anomaly is generated in the probe 102. Details of the position and function of the contact terminal 103 will be described below.

FIG. 1 further shows a wafer 201 to be measured. A plurality of semiconductor devices (not illustrated) are fabricated in the wafer 201. A TEG pad (TEG electrode) 202 is provided on a cutoff part (kerf) of the semiconductor devices on the wafer 201. The TEG pad 202 is an example of an electrode of a measurement object. FIG. 1 shows the wafer 201 installed on a measuring instrument chuck 203.

Hereafter, details of the configuration of the probe card in the present embodiment will be described.

FIG. 1 shows interconnects 111A and 111B formed on one surface of the substrate 101, and interconnects 111C and 111D formed on the other surface of the substrate 101. The probe 102 is disposed on the interconnect 111A (first interconnect), and the contact terminal 103 is disposed on the interconnect 111B (second interconnect). The interconnects 111A and 111B are electrically separated from each other on the substrate 101 in FIG. 1, and are electrically short-circuited when the probe 102 and the contact terminal 103 come in contact with each other as described below. The interconnect 111A is electrically connected to the interconnect 111C via a through hole 112A, and the interconnect 111B is electrically connected to the interconnect 111D via a through hole 112B.

As shown in FIG. 1, the probe 102 includes a probe support part 121 provided on the substrate 101, a probe beam part (arm part) 122 provided on the probe support part 121, and a pad contact part (bump part) 123 provided on a tip of the probe beam part 122. The probe beam part 122 is supported at a joint part P between the probe support part 121 and the probe beam part 122, serving as a fulcrum point, and extends in a direction along the surface of the substrate 101. In FIG. 1, the probe beam part 122 extends in a direction which is substantially parallel to the surface of the substrate 101. The pad contact part 123 serves as an electrode contact part which is brought into contact with the TEG pad 202 at the time of a TEG measurement of the wafer 201.

The probe support part 121, the probe beam part 122, and the pad contact part 123 may be formed of the same material, or may be formed of different materials. The names of the probe support part 121, the probe beam part 122, and the pad contact part 123 represent their functions in the probe 102, and it is not meant that these parts are physically different components. These parts may be formed of metal such as Ti (titanium) or W (tungsten), or may be formed of material other than metal.

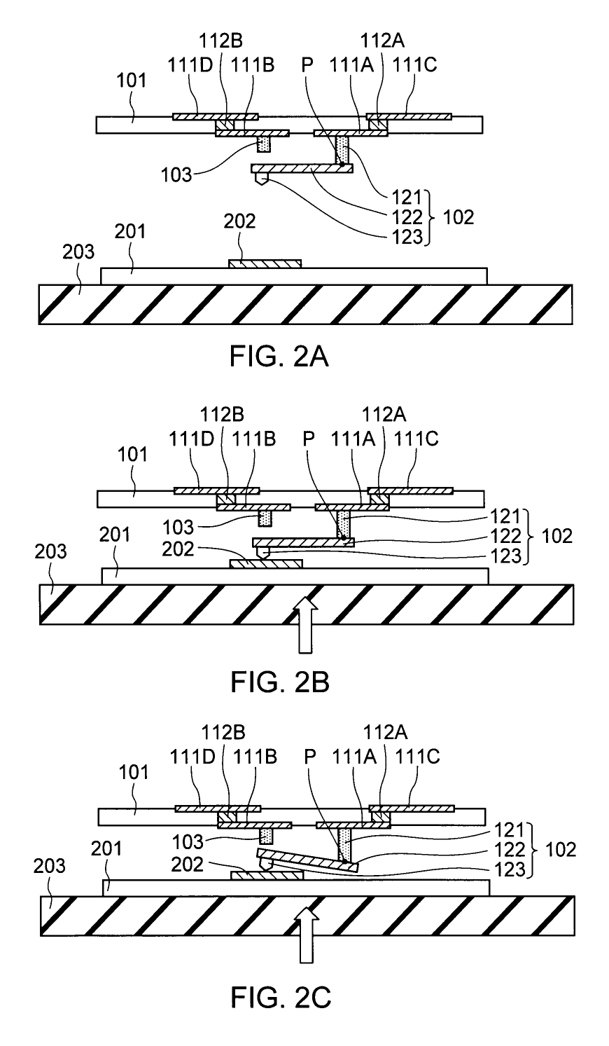

FIGS. 2A to 2C illustrate cross-sectional views showing the TEG measurement of the wafer 201.

FIG. 2A shows a state in which the wafer 201 is fed to a measurement position. In the TEG measurement, alignment data of the probe card and the wafer 201 are acquired in the state shown in FIG. 2A.

As the measuring instrument chuck 203 rises, the wafer 201 rises so as to bring the TEG pad 202 into contact with the pad contact part 123 as shown in FIG. 2B. Furthermore, the wafer 201 is raised up to an overdrive position shown in FIG. 2C. FIG. 2C shows a state in which a load is applied to the probe beam part 122 by the overdrive. Then, the TEG measurement is started in the present embodiment.

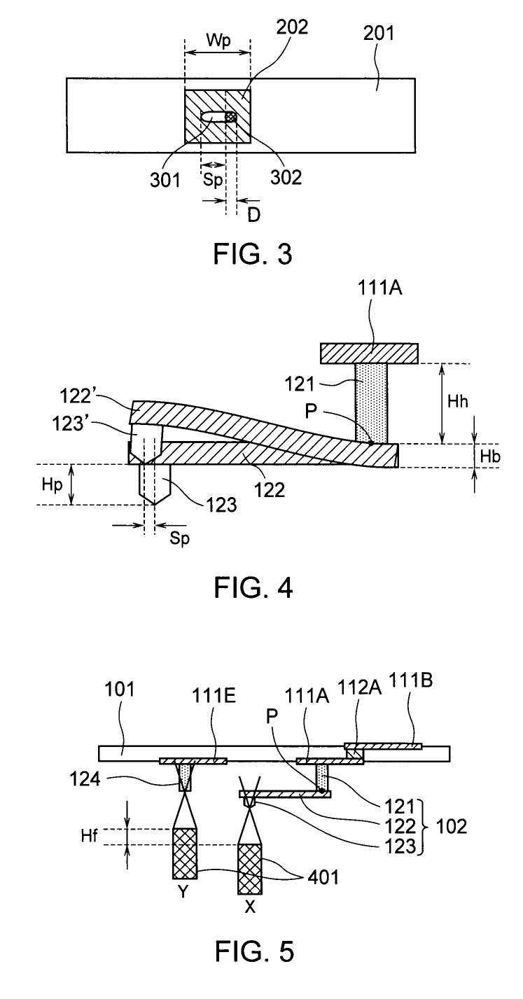

In the TEG measurement, a probe slip (probe deviation) is generated by the overdrive shown in FIG. 2C. FIGS. 3 and 4 are a top view and a cross-sectional view for explaining the probe slip.

In FIG. 3, a slip trace of the pad contact part 123 on the TEG pad 202 is denoted by 301, and an initial needle trace of the pad contact part 123 is denoted by 302. Furthermore, in FIG. 3, a dimension of the TEG pad 202 in the slip direction of the probe 102 is denoted by “Wp”, a length of the slip trace 301 (probe slip amount) is denoted by “Sp”, and a diameter of the initial needle trace 302 (initial needle trace diameter) is denoted by “D”.

It is necessary that the slip trace 301 and the initial needle trace 302 are contained within the TEG pad 202. Therefore, it is necessary that the sum of the length “Sp” of the slip trace 301 and the diameter “D” of the initial needle trace 302 is less than the dimension “Wp” of the TEG pad 202 (Sp+D<Wp).

FIG. 4 shows the probe beam part 122 and the pad contact part 123 before the load is applied, and the probe beam part 122 and the pad contact part 123 with the load applied. In FIG. 4, the probe beam part 122 and the pad contact part 123 with the load applied are especially denoted by 122′ and 123′, respectively.

Furthermore, in FIG. 4, the height (vertical width) of the probe support part 121 is denoted by “Hh”, the height (vertical width) of the probe beam part 122 is denoted by “Hb”, and the height (vertical width) of the pad contact part 123 is denoted by “Hp”. In addition, the length of the slip trace 301 of the pad contact part 123 is denoted by “Sp”, similarly to FIG. 3.

In the TEG measurement, a deflection is caused in the probe beam part 122 due to the load applied to the probe beam part 122 as shown in FIG. 4. FIG. 4 shows a state in which the height of the bottom part (tip) of the pad contact part 123 is made the same as the height of the bottom surface of the probe beam part 122 obtained before the load is applied, by the deflection of the probe beam part 122.

If the load is further increased from the state shown in FIG. 4 and the height of the bottom part of the pad contact part 123 becomes higher than the height of the bottom surface of the probe beam part 122 obtained before the load is applied, then the bottom surface of the probe beam part 122 comes in contact with the surface of the wafer 201. In the present embodiment, therefore, the load applied to the probe beam part 122 is restricted to within a range in which the height of the bottom part of the pad contact part 123 becomes lower than the height of the bottom surface of the probe beam part 122 obtained before the load is applied. In the present embodiment, the probe beam part 122 is designed to deal with the deflection of the probe beam part 122 in this range as an allowable deflection.

In the present embodiment, therefore, it is a condition to be satisfied that a distance “a” between the substrate 101 and the wafer 201 is greater than the sum of the height “Hh” of the probe support part 121 and the height “Hb” of the probe beam part 122 (α>Hh+Hb). Furthermore, it is a condition to be satisfied that an overdrive amount “β” of the measurement is less than the height “Hp” of the pad contact part 123 (β<Hp). In FIGS. 2A to 2C, the difference between the distance “a” from the substrate 101 to the wafer 201 in FIG. 2B and the distance “α” from the substrate 101 to the wafer 201 in FIG. 2C is the overdrive amount “β”.

Further, in FIG. 4, the length “Sp” of the slip trace 301 depends on the height “Hp” of the pad contact part 123. Therefore, in FIG. 3, the dimension “Wp” of the TEG pad 202 is designed by taking the height “Hp” of the pad contact part 123 into consideration.

If an accident of contact between the probe 102 and the wafer 201 occurs, there is a possibility that the probe 102 will sustain physical damage. As a method for detecting damage to the probe 102, for example, a method shown in FIG. 5 is known. FIG. 5 is a cross-sectional view showing a damage detection by using a CCD camera 401.

According to the method shown in FIG. 5, whether there is damage or not is managed optically by monitoring a focus difference between a tip of the probe 102 and a dummy pin 124 provided on an interconnect 111E with the CCD camera 401. The dummy pin 124 has the same structure as that of the probe support part 121. In FIG. 5, “X” and “Y” denote the positions of the CCD camera 401 at the time of measurement of the probe 102 and at the time of measurement of the dummy pin 124, respectively, and “Hf” denotes a distance of a deviation amount caused by the focus difference.

According to the method shown in FIG. 5, however, it is necessary to conduct an inspection at the time of an alignment adjustment prior to the TEG measurement. Therefore, there is a problem that it cannot be determined during the TEG measurement whether there is damage or not.

In the present embodiment, therefore, damage to the probe 102 is detected by detecting the shape anomaly of the probe 102 by using the contact terminal 103 shown in FIG. 1. Consequently, in the present embodiment, it is possible to detect damage during the TEG measurement as described below.

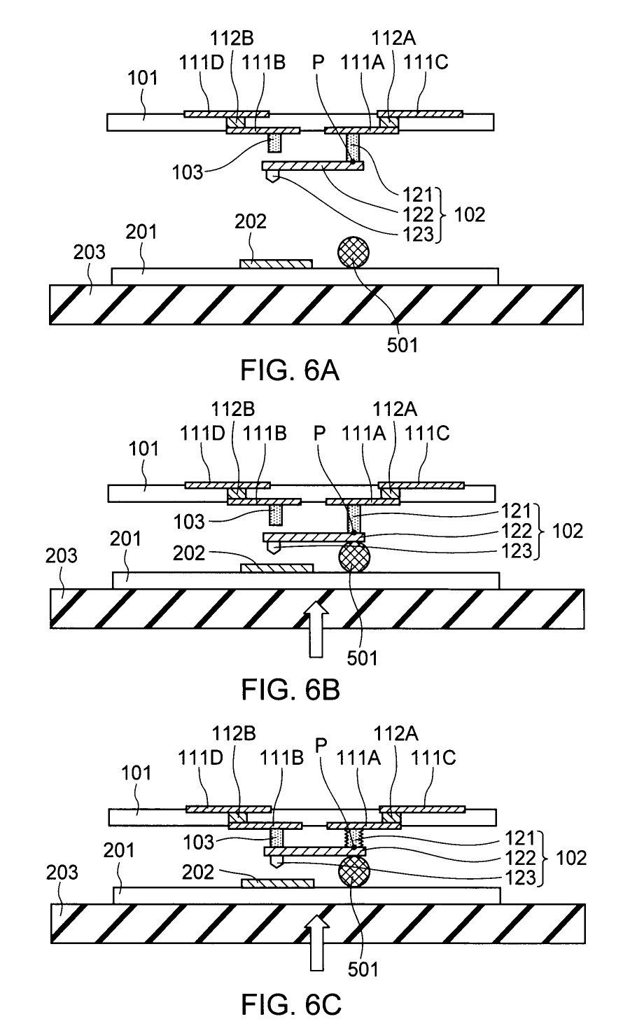

FIGS. 6A to 6C illustrate cross-sectional views showing an example of a generation process of the shape anomaly in the probe 102. Similarly to FIGS. 2A to 2C, FIGS. 6A to 6C illustrate cross-sectional views showing the TEG measurement of the wafer 201.

Similarly to FIG. 2A, FIG. 6A shows a state in which the wafer 201 is fed to the measurement position. In FIG. 6A, however, a particle 501 is attached on the wafer 201.

In the TEG measurement, then the wafer 201 rises as the measuring instrument chuck 203 rises as shown in FIG. 6B. As a result, in the case shown in FIG. 2B, the TEG pad 202 comes in contact with the pad contact part 123. However, in FIG. 6B, the particle 501 comes in contact with the probe beam part 122.

FIG. 6C shows a state in which an overdrive is further conducted from the state shown in FIG. 6B. FIG. 6C further shows a state in which the probe support part 121 is compressed and shrunk by the overdrive. Such a deformation of the probe support part 121 poses a problem that the resistance of the probe support part 121 changes and a measured value obtained by using the probe card becomes inaccurate. Such a deformation of the probe support part 121 is an example of the shape anomaly of the probe 102.

FIG. 6C further shows the probe beam part 122 which comes in contact with the contact terminal 103 as a result of the deformation of the probe support part 121. As described below, in the present embodiment, the shape anomaly is detected by using the contact between the probe beam part 122 and the contact terminal 103.

Hereafter, details of the contact terminal 103 will be described with reference to FIG. 1 again.

The contact terminal 103 is fixed on the interconnect 111B which is formed on the substrate 101, and is disposed right above the pad contact part 123. On the other hand, the probe 102 is provided on the interconnect 111A which is also formed on the substrate 101.

If there is not the shape anomaly in the probe 102, then the contact terminal 103 is not in contact with the probe 102. The contact terminal 103 is disposed at a position where the contact terminal 103 comes in contact with the probe 102 only when the shape anomaly is generated in the probe 102. Specifically in the present embodiment, the contact terminal 103 is disposed at a position where the contact terminal 103 comes in contact with the probe beam part 122 only when the shape anomaly is generated in the probe support part 121 or the probe beam part 122.

An example of the shape anomaly of the probe support part 121 is shown in FIGS. 6A to 6C. In FIGS. 6A to 6C, a deformation is generated in the probe support part 121 by a mechanical stress applied to the probe support part 121 as described above. On the other hand, an example of the shape anomaly of the probe beam part 122 is exactly what is described with reference to FIG. 4. In other words, in the present embodiment, the probe beam part 122 is designed so that a deflection of the probe beam part 122 within a range in which the height of the bottom part of the pad contact part 123 becomes lower than the height of the bottom surface of the probe beam part 122 prior to the load application is dealt with as an allowable deflection. The deflection which exceeds this range is the shape anomaly of the probe beam part 122.

If these shape anomalies are generated in the present embodiment, then the probe 102 comes in contact with the contact terminal 103, and thus the interconnects 111A and 111B are electrically short-circuited by the probe 102 and the contact terminal 103. In the present embodiment, the shape anomaly of the probe 102 can be sensed by utilizing a signal (current or voltage) flowing by the short circuit. The present embodiment has an advantage that damage to the probe 102 can be determined during the measurement because the shape anomaly is sensed by detecting the short circuit during the TEG measurement. According to the present embodiment, it is possible to always monitor an anomaly of the probe card.

In this way, it is possible according to the present embodiment to electrically sense the shape anomaly of the probe 102 during the TEG measurement. Consequently, in the present embodiment, it is possible to improve the reliability of acquired data and to achieve an improvement of the measurement throughput. In the present embodiment, the probe 102 and the contact terminal 103 are formed of materials which can conduct electric signals, such as conductors or semiconductors.

Parameters “Hs” and “Hh” shown in FIG. 1 will now be described. The parameter “Hs” denotes the height (vertical width) of the contact terminal 103, and the parameter “Hh” denotes the height (vertical width) of the probe support part 121, similarly to FIG. 4.

In the present embodiment, the height of the bottom part of the pad contact part 123 is restricted to become lower than the height of the bottom part of the probe beam part 122 prior to the load application as described above. A deflection of the probe beam part 122 which has exceeded this restriction becomes the shape anomaly of the probe beam part 122 (see FIG. 4). In the state shown in FIG. 4, therefore, the contact terminal 103 must not be in contact with the probe beam part 122. In FIG. 4, the distance between the bottom surface of the contact terminal 103 and the top surface of the probe beam part 122 is represented by (Hh+Hb−Hp)−Hs. A condition to be satisfied by “Hs” is that this distance is greater than zero.

In the present embodiment, therefore, the height “Hs” of the contact terminal 103 is set to be smaller than “Hh+Hb—Hp” (Hs<Hh+Hb−Hp). As a result, the contact terminal 103 does not come in contact with the probe beam part 122 under an ordinary deflection of the probe beam part 122, and comes in contact with the probe beam part 122 only when the shape anomaly is generated in the probe support part 121 or the probe beam part 122.

To make it possible to detect a slight shape anomaly, “Hs” should be set slightly smaller than “Hh+Hb−Hp”. On the other hand, in a case where a deflection of a height of approximately ΔH is allowed from the state shown in FIG. 4, “Hs” should be set approximately to “Hh+Hb−Hp−ΔH”.

In the present embodiment, it is possible to detect the shape anomaly of the probe support part 121 as well by setting the height “Hs” of the contact terminal 103 smaller than “Hh+Hb−Hp”. The reason will now be described. If there is not the shape anomaly in the probe support part 121, then contact between the probe 102 and the contact terminal 103 does not occur as long as there is not the shape anomaly of the probe beam part 122. On the other hand, if there is the shape anomaly in the probe support part 121, then contact between the probe 102 and the contact terminal 103 might occur when the deflection of the probe beam part 122 becomes great to a certain extent in an allowable range.

Hereafter, effects of the present embodiment will be described.

In the present embodiment, the contact terminal 103 is disposed at a position where the contact terminal 103 comes in contact with the probe 102 when the shape anomaly is generated in the probe 102, as described above. In the present embodiment, therefore, it is possible to detect the shape anomaly of the probe 102 during the measurement of the wafer 201.

Furthermore, in the present embodiment, the probe 102 and the contact terminal 103 are disposed on the first and second interconnects 111A and 111B, respectively. Consequently, if the shape anomaly is generated in the probe 102, the first and second interconnects 111A and 111B are electrically short-circuited to each other in the present embodiment. According to the present embodiment, therefore, it is possible to electrically detect the shape anomaly of the probe 102.

Furthermore, in the present embodiment, it is possible to provide the probe 102 with the configuration including the probe support part 121, the probe beam part 122, and the pad contact part 123 by using the MEMS technique or the like. In this case, for example, the contact terminal 103 is disposed at a position on the substrate 101 where the contact terminal 103 comes in contact with the probe beam part 122 when the shape anomaly is generated in the probe support part 121 or the probe beam part 122. Consequently, in the present embodiment, it is possible to detect the shape anomaly of the probe support part 121 or the probe beam part 122 during the measurement.

Owing to the parameter design which satisfies the relation “Hs<Hh+Hb−Hp”, it is possible in the present embodiment to detect the shape anomaly of the probe 102 by using the height of the tip of the probe beam part 122 as compared with the substrate 101 as a parameter. In the present embodiment, the shape anomaly of the probe 102 is detected by sensing that this height becomes less than “Hs”.

Hereafter, second and third embodiments will be described. Since these embodiments are modifications of the first embodiment, differences of these embodiments from the first embodiment are mainly described.

### Second Embodiment

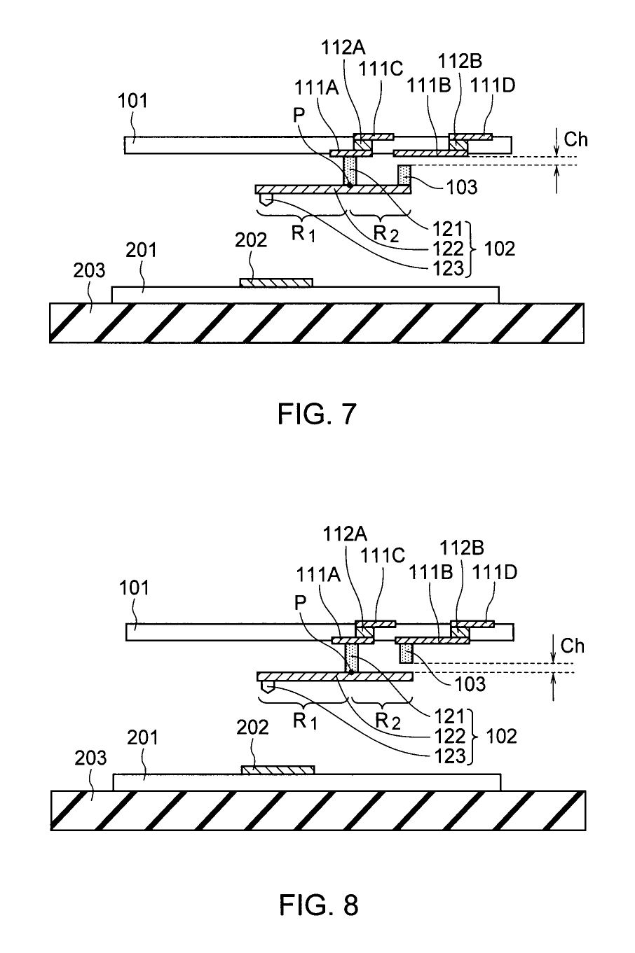

FIG. 7 is a cross-sectional view showing a configuration of a probe card according to a second embodiment.

In the first embodiment shown in FIG. 1, the contact terminal 103 is provided on the substrate 101. On the other hand, in the second embodiment shown in FIG. 7, the contact terminal 103 is provided on the probe 102. In the second embodiment, the contact terminal 103 is provided at a position on the probe 102 where the contact terminal 103 comes in contact with the substrate 101 when a shape anomaly is generated in the probe 102. In the second embodiment, therefore, it is possible to detect the shape anomaly of the probe 102 during the TEG measurement similarly to the first embodiment.

Furthermore, in the second embodiment, the probe 102 is disposed on the interconnect 111A, and the contact terminal 103 is provided at a position where the contact terminal 103 comes in contact with the interconnect 111B when the shape anomaly is generated in the probe 102. In the second embodiment, therefore, the interconnects 111A and 111B are electrically short-circuited to each other when the shape anomaly is generated in the probe 102. According to the second embodiment, therefore, it is possible to electrically detect the shape anomaly of the probe 102 by utilizing this short circuit.

Furthermore, in the second embodiment, the probe 102 includes the probe support part 121, the probe beam part 122, and the pad contact part 123 similarly to the first embodiment. The probe beam part 122 is supported at the joint part P between the probe support part 121 and the probe beam part 122, serving as the fulcrum point, and extends in the direction along the surface of the substrate 101. In FIG. 7, the probe beam part 122 extends in the direction which is substantially parallel to the surface of the substrate 101. The pad contact part 123 is provided on a bottom surface (on the wafer 201 side) of the probe beam part 122, and the contact terminal 103 is provided on a top surface (on the substrate 101 side) of the probe beam part 122.

In the following description, the fulcrum point is denoted by the character P.

The probe beam part 122 can be divided at the fulcrum point P into a first region R₁ and a second region R₂. The first region R₁ is located where it includes the pad contact part 123, whereas the second region R₂ is located where it does not include the pad contact part 123. The probe 102 in the present embodiment has a structure in which the probe beam part 122 is extended from the first region R₁ to the second region R₂.

In the present embodiment, the contact terminal 103 is provided on the opposite side from the pad contact part 123 with respect to the fulcrum point P, on the probe beam part 122. In other words, the pad contact part 123 is disposed in the first region R₁, whereas the contact terminal 103 is disposed in the second region R₂ which is on the opposite side from the first region R₁.

Such a disposition of the contact terminal 103 has the following advantages.

At the time of the TEG measurement, there is a temperature difference between the pad contact part 123 and the TEG pad 202 in some cases. In these cases, there is a possibility that the probe beam part 122 in the first region R₁ located near the pad contact part 123 will be deformed by this temperature difference. Therefore, if the contact terminal 103 is disposed in the first region R₁, there is a possibility that a shape anomaly will be detected although there is not originally a shape anomaly, or that a shape anomaly will not be detected although there is originally a shape anomaly.

On the other hand, the possibility that the probe beam part 122 in the second region R₂, which is remote from the pad contact part 123, will be deformed by the temperature difference is small. Therefore, if the contact terminal 103 is disposed in the second region R₂, detection errors caused by the temperature difference can be reduced.

In the first embodiment, the contact terminal 103 is disposed right above the pad contact part 123, i.e., above the first region R₁. In the first embodiment, therefore, it is possible to detect the shape anomaly of the probe beam part 122 as well in addition to the shape anomaly of the probe support part 121. This is useful in the case where it is desirable to detect not only the shape anomaly of the probe support part 121 but also the shape anomaly of the probe beam part 122. However, in the case where it is desirable to detect only the shape anomaly of the probe support part 121 which is the original object to be detected, the first embodiment is not suitable. If it is attempted to detect only the shape anomaly of the probe support part 121 in the first embodiment, there is a problem that the setting of the height “Hs” of the contact terminal 103 is complicated because there is also the problem of the temperature difference.

On the other hand, in the present embodiment, the contact terminal 103 is disposed on the probe beam part 122 in the second region R₂. In the present embodiment, therefore, it is possible to detect only the shape anomaly of the probe support part 121 which is the original object to be detected.

In FIG. 7, a clearance between the contact terminal 103 and the interconnect 111B is denoted by “Ch”. In the present embodiment, it is necessary to dispose the contact terminal 103 and the interconnect 111B at positions where they come in contact with each other only when the shape anomaly is generated in the probe support part 121. Therefore, a condition to be satisfied is that the clearance “Ch” is greater than zero (Ch>0).

To make it possible to detect even a slight shape anomaly of the probe support part 121, “Ch” should be set slightly greater than zero. On the other hand, in a case where a compression of the probe support part 121 of approximately “ΔC” is allowable, “Ch” should be set approximately to “ΔC”.

Hereafter, effects of the present embodiment will be described.

In the present embodiment, the contact terminal 103 is disposed at a position on the probe 102 where the contact terminal 103 comes in contact with the substrate 101 when the shape anomaly is generated in the probe 102. Consequently, in the present embodiment, it is possible to detect the shape anomaly of the probe 102 during the measurement of the wafer 201, similarly to the first embodiment. In addition, when fabricating the probe 102 by using a precision process technique such as the MEMS technique, it is possible to fabricate the contact terminal 103 as well simultaneously in the process of fabricating the probe 102. Consequently, the process of mounting the contact terminal 103 and the like can be omitted. The probe 121, the probe beam part 122, the pad contact part 123, and the contact terminal 103 may be formed of the same material, or may be formed of different materials.

Furthermore, in the present embodiment, the probe 102 is disposed on the first interconnect 111A, and the contact terminal 103 is disposed at a position where the contact terminal 103 comes in contact with the second interconnect 111B when the shape anomaly is generated in the probe 102. Consequently, in the present embodiment, it is possible to electrically detect the shape anomaly of the probe 102 by utilizing the short circuit between these interconnects, similarly to the first embodiment.

Furthermore, in the present embodiment, it is possible to provide the probe 102 with the configuration including the probe support part 121, the probe beam part 122, and the pad contact part 123 by utilizing the MEMS technique or the like. In this case, for example, the contact terminal 103 is provided on the opposite side from the pad contact part 123 with respect to the fulcrum point P, on the probe beam part 122. Consequently, in the present embodiment, it is possible to decrease detection errors caused by a temperature difference between the pad contact part 123 and the TEG pad 202. Further, it is possible to detect only the shape anomaly of the probe support part 121 among the shape anomaly of the probe support part 121 and the shape anomaly of the probe beam part 122. In addition, it is possible to design the contact terminal 103 without considering the clearance of the operation part of the probe 102 in design.

As shown in FIG. 8, the contact terminal 103 may not be provided on the probe beam part 122 in the second region R₂, but may be provided at a position on the substrate 101 (interconnect 111B) where the contact terminal 103 comes in contact with the second region R₂ when the shape anomaly is generated in the probe 102 (probe support part 121). FIG. 8 is a cross-sectional view showing a configuration of a probe card according to a modification of the second embodiment. According to the present modification, effects similar to those in the second embodiment can be obtained. In the present modification, “Ch” is a clearance between the contact terminal 103 and the probe beam part 122.

### Third Embodiment

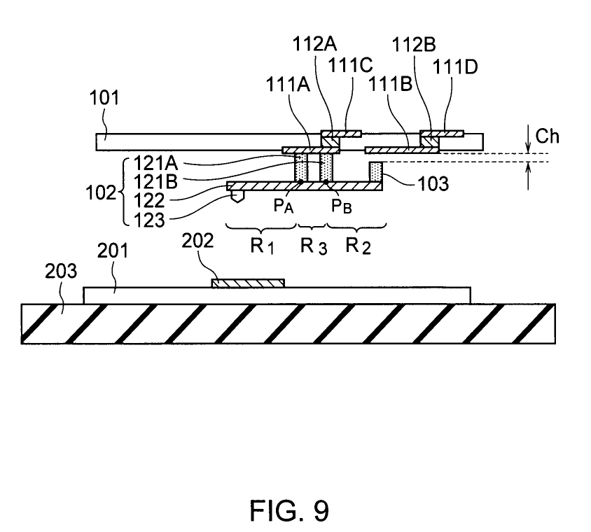

FIG. 9 is a cross-sectional view showing a configuration of a probe card according to a third embodiment.

In the second embodiment shown in FIG. 7, the probe beam part 122 is provided on one probe support part 121. On the other hand, in the third embodiment shown in FIG. 9, the probe beam part 122 is provided on a plurality of probe support parts 121. In FIG. 9, these probe support parts 121 are disposed on the same interconnect 111A.

The probe beam part 122 provided on two probe support parts 121A and 121B is shown in FIG. 9. A joint part P_{A} between the probe support part 121A and the probe beam part 122, and a joint part P_{B} between the probe support part 121B and the probe beam part 122 are further shown in FIG. 9. The probe beam part 122 is supported at the joint part P_{A} between the probe support part 121A and the probe beam part 122 and at the joint part P_{B} between the probe support part 121B and the probe beam part 122, serving as fulcrum points, and extends in the direction along the surface of the substrate 101. In FIG. 9, the probe beam part 122 extends in the direction which is substantially parallel to the surface of the substrate 101.

In the following description, the fulcrum points are denoted by P_{A} and P_{B}.

The probe beam part 122 can be divided at the fulcrum points P_{A} and P_{B} into first to third regions R₁ to R₃. The first and second regions R₁ and R₂ are located where they include one end and the other end of the probe beam part 122, respectively. Among the first and second regions R₁ and R₂, the first region R₁ is located where it includes the pad contact part 123, and the second region R₂ is located where it does not include the pad contact part 123. The third region R₃ is located where it is sandwiched between the fulcrum point P_{A} and the fulcrum point P_{B}.

In the present embodiment, the contact terminal 103 is provided on the opposite side from the pad contact part 123 with respect to the fulcrum points P_{A} and P_{B}, on the probe beam part 122. In other words, the pad contact part 123 is disposed in the first region R₁ which includes a first end of the probe beam part 122, whereas the contact terminal 103 is disposed in the second region R₂ which includes a second end which is on the opposite side from the first end. In the present embodiment, therefore, it is possible to decrease detection errors caused by the temperature difference between the pad contact part 123 and the TEG pad 202, and it is possible to detect only the shape anomaly of the probe support part 121 among the shape anomaly of the probe support part 121 and the shape anomaly of the probe beam part 122, similarly to the second embodiment.

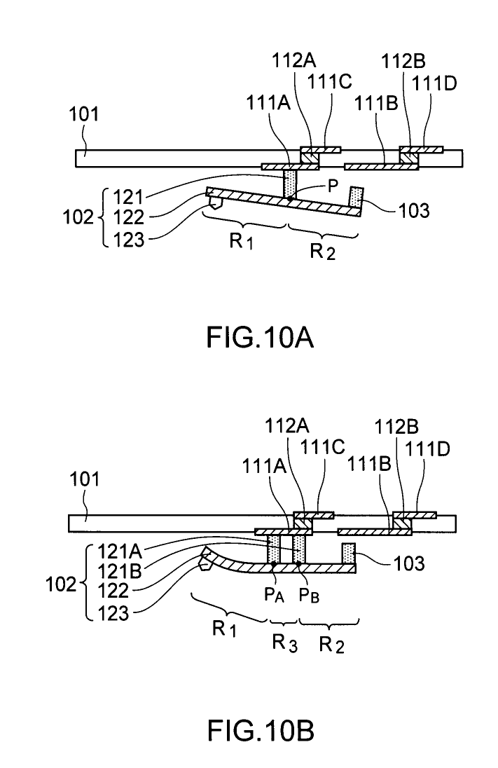

The second and third embodiment will now be compared with each other with reference to FIGS. 10A and 10B. FIGS. 10A and 10B show cross-sectional views for comparing advantages of probe structures between the second and third embodiments.

In the second embodiment, the probe beam part 122 is supported by one fulcrum point P as shown in FIG. 10A. In the second embodiment, therefore, a strain of the probe beam part 122 in the first region R₁ is easily conducted to the probe beam part 122 in the second region R₂. In the second embodiment, therefore, the precision of the clearance “Ch” falls, and it is difficult to set the clearance “Ch”. FIG. 10A shows the probe beam part 122 in the second region R₂ which falls due to rise of the probe beam part 122 in the first region R₁.

On the other hand, in the third embodiment, the probe beam part 122 is supported by a plurality of fulcrum points P_{A} and P_{B} as shown in FIG. 10B. In the third embodiment, therefore, a strain of the probe beam part 122 in the first region R₁ is hard to be conducted to the probe beam part 122 in the second region R₂. In the third embodiment, therefore, the precision of the clearance “Ch” is secured, and it is possible to obtain a stable clearance “Ch”. FIG. 10B shows the probe beam part 122 in the second region R₂ which is kept horizontal though the probe beam part 122 in the first region R₁ rises.

In the present embodiment, the probe beam part 122 is supported by a plurality of probe support parts 121 as described above. Consequently, in the present embodiment, it is possible to prevent the strain on the first end side of the probe beam part 122 from being conducted to the second end side of the probe beam part 122. Such a configuration is effective especially to the case where the contact terminal 103 is disposed on the opposite side from the pad contact part 123 with respect to the fulcrum points P_{A} and P_{B}, on the probe beam part 122. Consequently, the precision of the clearance “Ch” is secured, and it is possible to obtain a stable clearance “Ch”.

The structure in which the probe beam part 122 is supported by a plurality of probe support parts 121 can be applied to the first embodiment (FIG. 1) and the modification of the second embodiment (FIG. 8).

According to the embodiments described herein, it is possible to provide a probe card having a mechanism capable of detecting the shape anomaly of the probe as described above.

While certain embodiments have been described, these embodiments have been presented by way of example only, and are not intended to limit the scope of the inventions. Indeed, the novel probe cards described herein may be embodied in a variety of other forms; furthermore, various omissions, substitutions and changes in the form of the probe cards described herein may be made without departing from the sprit of the inventions. The accompanying claims and their equivalents are intended to cover such forms or modifications as would fall within the scope and sprit of the inventions.

1. A probe card comprising:
a substrate;
a probe provided on the substrate; and
a contact terminal provided at a position on the substrate where the contact terminal comes in contact with the probe when a shape anomaly is generated in the probe.

2. The card according to claim 1, wherein
the probe includes:
a probe support part provided on the substrate;
a probe beam part provided on the probe support part, and configured to be supported at a joint part between the probe support part and the probe beam part, serving as a fulcrum point, and to extend in a direction along a surface of the substrate; and
an electrode contact part provided on the probe beam part, and configured to be brought into contact with an electrode of a measurement object.

3. The card according to claim 2, wherein
the contact terminal is provided at the position on the substrate where the contact terminal comes in contact with the probe beam part when the shape anomaly is generated in the probe support part or the probe beam part.

4. The card according to claim 2, wherein
“Hs” is set smaller than “Hh+Hb−Hp”, where “Hs” is a height of the contact terminal, “Hh” is a height of the probe support part, “Hb” is a height of the probe beam part, and “Hp” is a height of the electrode contact part.

5. The card according to claim 1, further comprising first and second interconnects formed on the substrate,
wherein the probe is provided on the first interconnect, and the contact terminal is provided on the second interconnect.

6. The card according to claim 5, wherein
the probe and the contact terminal are formed of materials capable of conducting electric signals.

7. The card according to claim 5, wherein
the first and second interconnects are electrically separated on the substrate, and are electrically short-circuited when the probe and the contact terminal come in contact with each other.

8. The card according to claim 2, wherein
the probe beam part is divided at the fulcrum point into a first region located on the electrode contact part side and a second region located on an opposite side from the electrode contact part, and
the contact terminal is provided at the position on the substrate where the contact terminal comes in contact with the second region of the probe beam part when the shape anomaly is generated in the probe support part.

9. The card according to claim 2, wherein the probe includes a plurality of probe support parts provided on the substrate.

10. The card according to claim 9, wherein
the plurality of probe support parts are provided on the same interconnect formed on the substrate.

11. The card according to claim 2, wherein
the probe support part, the probe beam part, and the electrode contact part are formed of the same material.

12. A probe card comprising:
a substrate;
a probe provided on the substrate; and
a contact terminal provided at a position on the probe where the contact terminal comes in contact with the substrate when a shape anomaly is generated in the probe.

13. The card according to claim 12, wherein
the probe includes:
a probe support part provided on the substrate;
a probe beam part provided on the probe support part, and configured to be supported at a joint part between the probe support part and the probe beam part, serving as a fulcrum point, and to extend in a direction along a surface of the substrate; and
an electrode contact part provided on the probe beam part, and configured to be brought into contact with an electrode of a measurement object.

14. The card according to claim 13, wherein
the probe beam part is divided at the fulcrum point into a first region located on the electrode contact part side and a second region located on an opposite side from the electrode contact part, and
the contact terminal is provided in the second region on the probe beam part.

15. The card according to claim 12, further comprising first and second interconnects formed on the substrate,
wherein the probe is provided on the first interconnect, and the contact terminal is provided at the position on the probe where the contact terminal comes in contact with the second interconnect when the shape anomaly is generated in the probe.

16. The card according to claim 15, wherein
the probe and the contact terminal are formed of materials capable of conducting electric signals.

17. The card according to claim 15, wherein
the first and second interconnects are electrically separated on the substrate, and are electrically short-circuited when the contact terminal and the second interconnect come in contact with each other.

18. The card according to claim 13, wherein the probe includes a plurality of probe support parts provided on the substrate.

19. The card according to claim 18, wherein
the plurality of probe support parts are provided on the same interconnect formed on the substrate.

20. The card according to claim 13, wherein
the probe support part, the probe beam part, and the electrode contact part are formed of the same material.
